(19) United States
(12) Patent Application Publication
(10) Pub. No.: US 2025/0308852 A1
(43) Pub. Date: Oct. 2, 2025

(54) DYNAMIC FREQUENCY TUNING FOR MICROWAVE POWER AMPLIFIERS

(71) Applicant: Applied Materials, Inc., Santa Clara, CA (US)

(72) Inventors: XIAOKANG YANG, Fremont, CA (US); VISHESH SESHADRI, Santa Clara, CA (US); MANASAKIRAN RAVIKIRAN, San Jose, CA (US); SALONI SAWALKAR, San Ramon, CA (US); SANJEEV BALUJA, Campbell, CA (US)

(21) Appl. No.: 18/624,990

(22) Filed: Apr. 2, 2024

(51) Int. Cl. H01J 37/32

(52) U.S. Cl. CPC H01J 37/32256; H01J 37/32302; H01J 37/32311; H01J 37/32935

(57) ABSTRACT

In some aspects, the embodiments described herein relate to a method for tuning a frequency of microwave power delivered to a chamber, including striking a plasma in the chamber. Embodiments may further comprise scanning the frequency from a first frequency to a second frequency, where a set point frequency in a range from the first frequency to the second frequency has a lowest reflected power. In an embodiment, the method further includes setting the frequency of the microwave power delivered to the chamber to the set point frequency. The method may further include changing the set point frequency when a measure of reflected power exceeds a threshold.

### BACKGROUND

### 1) Field

Embodiments relate to the field of semiconductor manufacturing and, in particular, to processes for frequency tuning for microwave power amplifiers for plasma processing operations.

### 2) Description of Related Art

In plasma processing tools, a power delivery channel is provided in order to deliver power (e.g., radio frequency (RF) power or microwave power) to the chamber. The power delivery channel may include a power supply that is coupled to a power amplifier, a coaxial cable, an impedance match, and an antenna. Ideally, the power delivery channel is tuned in order to minimize reflected power back into the power delivery channel. This may be done by matching an impedance of the power delivery channel to the impedance of the load (e.g., the plasma within the chamber). Reducing the reflected power is beneficial since reflected power can cause damage to the power delivery channel and reduces efficiency of the power delivery channel. For example, high levels of reflected power can negatively impact and/or damage the power amplifier, coaxial interconnects, etc.

### SUMMARY

In some aspects, the embodiments described herein relate to a method for tuning a frequency of microwave power delivered to a chamber, including striking a plasma in the chamber. Embodiments may further comprise scanning the frequency from a first frequency to a second frequency, where a set point frequency in a range from the first frequency to the second frequency has a lowest reflected power. In an embodiment, the method further includes setting the frequency of the microwave power delivered to the chamber to the set point frequency. The method may further include changing the set point frequency when a measure of reflected power exceeds a threshold.

In some aspects, the techniques described herein relate to an apparatus, including a microwave power amplifier, where the microwave power amplifier includes a sweep generator. In an embodiment, an impedance match is coupled to the microwave power amplifier, and an antenna is coupled to the impedance match. In an embodiment, the apparatus may further comprise a controller that is communicative coupled to the microwave power amplifier and configured to control the sweep generator.

In some aspects, the techniques described herein relate to a method for frequency tuning a multi-channel power amplifier system, including scanning a plurality of power amplifiers through a frequency range from a first frequency to a second frequency. The method may further comprise setting each of the plurality of power amplifiers to a set point frequency that provides a lowest reflected power, and auto tuning each of the plurality of power amplifiers during a process recipe. In an embodiment, the auto tuning includes changing the set point frequency for each of the plurality of power amplifiers.

### BRIEF DESCRIPTION OF THE DRAWINGS

FIG. 1A is a cross-sectional illustration of a semiconductor processing tool for generating a microwave plasma using a plurality of dielectric resonator antennas (DRAs), in accordance with an embodiment.

FIG. 1B is a plan view illustration of a DRA array over a dielectric plate for use in a microwave plasma semiconductor processing tool, in accordance with an embodiment.

FIG. 2 is a schematic illustration of the microwave power delivery system of a semiconductor processing tool for generating a microwave plasma, in accordance with an embodiment.

FIG. 3 is a schematic illustration of a microwave power delivery system with a plurality of power delivery channels, where each channel includes a sweep generator that is coupled to a controller, in accordance with an embodiment.

FIG. 4 is a process flow diagram of a process for tuning the frequency of power amplifier of a microwave power delivery channel for minimizing reflected power, in accordance with an embodiment.

FIG. 5 is a process flow diagram of a process for auto-tuning a frequency after a frequency sweep, in accordance with an embodiment.

FIG. 6 is a graph of frequency over time during a microwave power delivery tuning process during a process recipe, in accordance with an embodiment.

FIG. 7A is a plot of a process for tuning a microwave frequency during a recipe with multiple pulses, in accordance with an embodiment.

FIG. 7B is a plot of a process for tuning a microwave frequency during a recipe with multiple pulses where each pulse includes two different gas flows, in accordance with an embodiment.

FIG. 7C is a plot of a process for tuning a microwave frequency during a recipe with a single continuous gas flow, in accordance with an embodiment.

FIG. 8 illustrates a block diagram of an exemplary computer system that may be used in conjunction with a processing tool, in accordance with an embodiment.

### DETAILED DESCRIPTION

Embodiments described herein include apparatuses and processes for tuning frequencies of microwave power amplifiers in order to reduce reflected power. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

Microwave plasma sources have seen a growth in importance in semiconductor processing environments. This can be due, at least in part, to the improved plasma performance that is provided when a microwave power source is used. Compared to traditional RF based plasmas (e.g., a capacitively coupled plasma (CCP), inductively coupled plasma (ICP), etc.), the flux of radicals provided to the substrate is higher for the microwave plasma. That is, a plasma density of the microwave plasma may be higher. At the same time, the ion energy at the substrate surface for a microwave plasma is lower than the ion energy at the substrate surface for a typical RF based plasma. More particularly, the ion energy is typically well below a general damage threshold of approximately 30 eV.

Previous attempts to provide microwave power sources relied on magnetron solutions. The use of magnetrons results in bulky and hard to control systems. Magnetron solutions for implementing impedance matching are particularly problematic when a multi-channel microwave plasma tool is desired. A standard impedance matching solution for magnetron based architectures use a fixed frequency with a stub tuner (e.g., comprising a single stub or multiple stubs). Stub tuners are mechanically displaceable stubs that short-circuit a section of transmission line along the main signal line. By changing the positioning and/or geometry of the stubs, a variable impedance can be provided. Accordingly, the stubs and the associated actuators occupy a relatively large space. When a single microwave power delivery channel is used, this extra space is not particularly problematic. However, when multi-channel solutions are used, each channel needs a dedicated stub (or group of stubs) and the associated actuators. This can greatly increase the overall size of the tool, while also adding to the complexity of stub control. As such, it quickly becomes impractical to use multiple stub tuner solutions.

Accordingly, solid state solutions have been suggested for microwave power supplies. Solid state solutions provide enhanced control, while also shrinking the form factor of the power delivery system. One benefit of a reduced form factor is that a plurality of microwave channels can be used for a single processing tool. Instead of a fixed frequency, the solid state power amplifiers allow for variable frequency operation. Through control of various parameters of each microwave channel, the impedance matching can also be optimized to minimize or eliminate reflected power in the system.

However, existing tuning functionality is limited, even with solid state solutions. Particularly, existing power amplifier tuning is slow and is done on an individual basis. For example, tuning the frequency of each power amplifier may require up to three minutes. For a multi-channel tool, such as those described herein, this may require over an hour of tuning before the tool can be used for processing substrates. Since the tuning is a time intensive process, multi-operation processing recipes (e.g., the flow of different gasses into the chamber during a single recipe) are difficult to optimize as well. The use of variable impedance matches may provide some benefits, but the inclusion and control of a plurality of variable impedance matches (e.g., one for each power delivery channel) is unmanageable in high volume manufacturing tools.

Accordingly, embodiments disclosed herein include microwave plasma tools that comprises a multi-channel microwave power delivery system, where each of the power amplifiers include a frequency tuning component. In an embodiment, the frequency tuning component may comprise a sweep generator that allows for a rapid sweep through a frequency range. During the frequency sweep, the frequency with the lowest reflected power is set as a set-point frequency. Thereafter, the set-point frequency is monitored with an auto-tuning process in order to maintain a low reflected power throughout a process recipe.

The frequency sweep may be implemented rapidly (e.g., in less than 100 ms). As such, multiple frequency sweeps can be implemented throughout a processing recipe in order to maintain a low reflected power even as conditions within the chamber change (e.g., due to the flow of different gasses or the like). Additionally, the frequency sweep can be implemented on each of the microwave power delivery channels in parallel.

Accordingly, the frequency tuning process that previously took over an hour to accomplish can be implemented during the process recipe itself. This allows for significant increases in tool up time after planned maintenance (PM) and/or changes to the microwave power delivery channel and/or hardware changes throughout the tool. Embodiments disclosed herein also allow for an increase in the operation window of a given tool to allow for different processing recipes to be implemented without the need for extensive down time to tune each separate process recipe. Further, a single microwave plasma tool may be used for different types of processing, such as plasma enhanced atomic layer deposition (PEALD), plasma enhanced chemical vapor deposition (PECVD), annealing, plasma cleans, and/or plasma treatments.

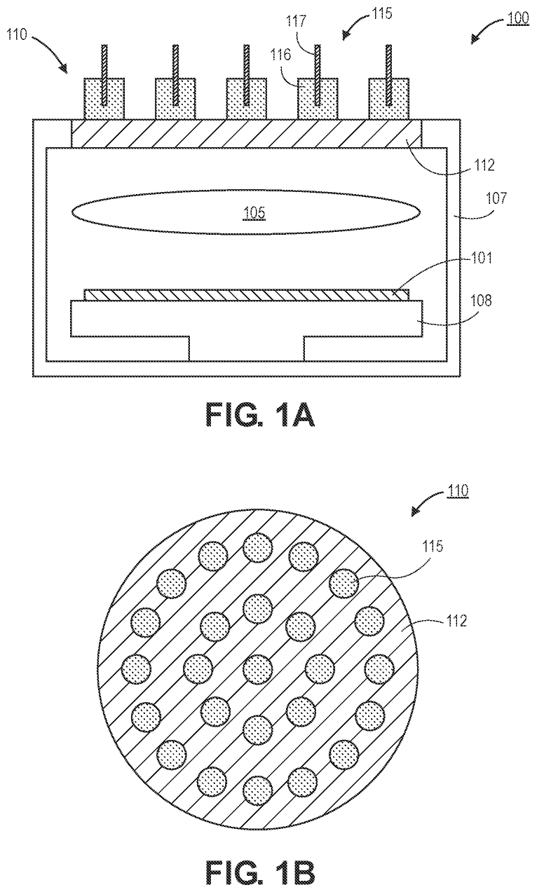

An example of a multi-channel microwave plasma tool is shown in FIG. 1A. Referring now to FIG. 1A, a cross-sectional illustration of a semiconductor processing tool 100 is shown, in accordance with an embodiment. The semiconductor processing tool 100 may be a tool that processes a substrate 101 with plasma 105 that is generated through the use of microwave power. In an embodiment, the tool 100 may be a plasma deposition tool (e.g., a microwave PECVD, a microwave PEALD, etc.), a microwave plasma etching tool, a microwave plasma treatment tool, and/or the like. The substrate 101 may be any substrate suitable for fabricating semiconductor structures. For example, the substrate 101 may be a silicon wafer or any other semiconductor wafer. The substrate 101 may include any suitable form factor, such as a 300 mm diameter, a 400 mm diameter, or the like. In an embodiment, the substrate 101 may be supported on a pedestal 108. The pedestal may comprise a chucking device for securing the substrate 101 during processing. The chucking device may comprise an electrostatic chuck (ESC) or the like.

In an embodiment, the tool 100 may comprise a chamber 107. The chamber 107 may be suitable for supporting a vacuum environment within the chamber 107. The vacuum environment may be at a pressure suitable for the formation of the plasma 105. That is, a “vacuum environment” does not necessarily mean that a perfect vacuum environment is necessary. For example, the chamber 107 may support a rough vacuum (e.g., a pressure up to approximately 800 Torr). Though, higher vacuum environments (i.e., lower pressures) may also be supported by the chamber 107. The low pressure environment may be provided through the use of an exhaust, a vacuum pump, and/or the like (not shown for simplicity). The chamber 107 may also include a slit valve (not shown) for passing the substrate 101 into and out of the chamber 107.

In an embodiment, the tool 100 may comprise a lid assembly 110. The lid assembly 110 may comprise a dielectric plate 112 that is provided opposite of the pedestal 108. The dielectric material of the dielectric plate 112 may comprise a ceramic in some embodiments. The dielectric plate 112 may comprise pathways, channels, holes, and/or the like (not shown) for distributing gasses into the chamber 107. In some instances, the dielectric plate 112 may be referred to as a showerhead. In an embodiment, a plurality of dielectric resonator antennas (DRAs) 115 may be distributed across the top surface of the dielectric plate 112. The DRAs 115 may each comprise a puck 116 and a pin 117 that is inserted into a hole into the top surface of the puck 116.

In an embodiment, the puck 116 is a dielectric material, such as a ceramic material or the like. The puck 116 may be the same dielectric material as the dielectric plate 112. Though, in other embodiments, the puck 116 and the dielectric plate 112 may be different materials. In an embodiment, the puck 116 is a cylindrical shaped object. Though, other axially symmetric shapes may also be used in some embodiments. The dimensions and material of the puck 116 may be chosen in order to set a desired resonant frequency for coupling microwave power into the plasma 105.

In an embodiment, the pin 117 is an electrically conductive pin (e.g., copper). The pin 117 may be inserted into the hole of the puck 116 to a desired depth. The depth into the puck 116 can be controlled in order to provide a desired response. In an embodiment, the opposite end of the pin 117 is coupled to a remainder of the microwave power supply system (which will be described in greater detail below). For example, the pin 117 may be coupled to an impedance match.

In the illustrated embodiment, the DRA 115 is shown as a bare dielectric material puck 116 with an electrically conductive pin 117. However, it is to be appreciated that the DRA 115 may comprise a housing that surrounds portions (or all of) the DRA 115. For example, an electrically conductive housing may be provided around the DRA 115. The electrically conductive housing may be grounded in some embodiments. In an embodiment, the housing may comprise aluminum or the like.

Referring now to FIG. 1B, a plan view illustration of a lid assembly 110 is shown, in accordance with an embodiment. In an embodiment, the lid assembly 110 may be similar to the lid assembly 110 described above with respect to FIG. 1A. For example, the lid assembly 110 may comprise a dielectric plate 112. The dielectric plate 112 in FIG. 1B is shown as being circular. Though, in other embodiments, the dielectric plate 112 may have any shape. The dielectric plate 112 may comprise a ceramic material in some embodiments.

In an embodiment, a plurality of DRAs 115 may be distributed across the dielectric plate 112. The DRAs 115 may be similar to the DRAs 115 described above with respect to FIG. 1A. For example, each DRA 115 may comprise a puck and a pin. A housing may also surround the puck and pin of each DRA 115. In the illustrated embodiment, twenty five DRAs 115 are distributed across the dielectric plate 112. Though, it is to be appreciated that one or more DRAs 115 may be included in the lid assembly 110 in other embodiments. In a particular embodiment, nineteen DRAs 115 are provided on the dielectric plate 112.

In an embodiment, the layout of the plurality of DRAs 115 may include any suitable pattern. In a particular embodiment, the DRAs 115 may be provided in a symmetric pattern about the dielectric plate 112. Embodiments may also include a series of DRA 115 rings that are substantially concentric with each other, as shown in FIG. 1B. Other packing configurations may also be used in order to provide denser DRA 115 layouts.

The use of a plurality of DRAs 115 allows for greater control of the processing environment within the chamber 107. That is, the plasma 105 can be controlled with greater spatial variation. This allows for different plasma parameters to be applied to (for example) the center of the substrate 101 and the edge of the substrate 101. Variable control in this manner can lead to improved overall processing uniformity.

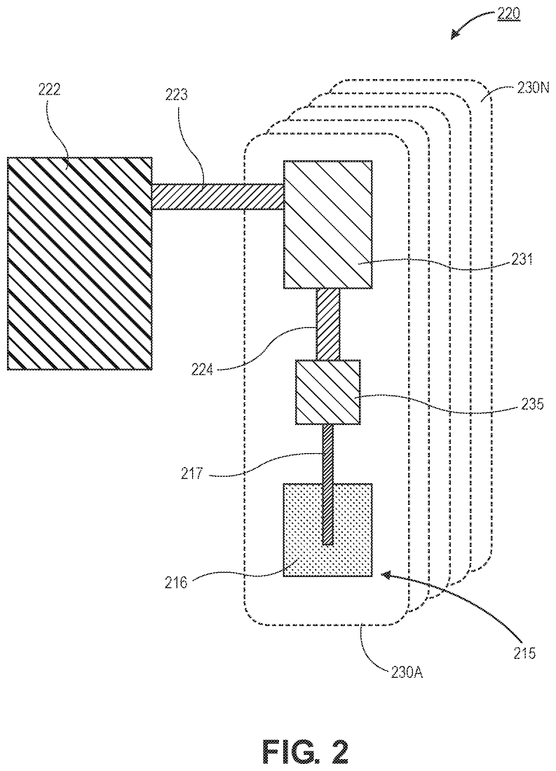

Referring now to FIG. 2, a schematic illustration of a microwave power delivery system 220 is shown, in accordance with an embodiment. In an embodiment, the microwave power delivery system 220 may be coupled to a plasma processing tool similar to the tool 100 described in greater detail herein. The microwave power delivery system 220 may be a solid state microwave power delivery system 220. That is, the microwaves may be generated without the use of a magnetron or the like. Accordingly, a plurality of microwave power delivery channels 230 may be included within a reasonable form factor. In FIG. 2, microwave power delivery channels 230A to 230N are provided as an example. The number of microwave power delivery channels 230 may be equal to the number of DRAs that are desired for the tool. For example, there may be one or more microwave power delivery channels 230, ten or more microwave power delivery channels 230, or twenty or more microwave power delivery channels 230. In a particular embodiment, there may be nineteen microwave power delivery channels 230.

In an embodiment, the microwave power delivery system 220 may comprise a power supply 222. A single power supply 222 may supply power to each of the microwave power delivery channels 230. For example, coaxial cables 223 may electrically couple the power supply 222 to the plurality of microwave channels 230. The power supply 222 may be an AC/DC power supply in some embodiments. More particularly, the power supply 222 may be a solid state microwave power supply 222. While a single power supply 222 is shown in FIG. 2, it is to be appreciated that two or more power supplies 222 may be used in the power delivery system 220 in other embodiments.

In an embodiment, the microwave power delivery channels 230 may each comprise a plurality of components that take the microwave power and deliver it to the plasma processing tool. In an embodiment, the microwave power delivery channel 230 may comprise a microwave power amplifier 231, such as a solid state microwave power amplifier. The microwave power amplifier may be electrically coupled to an impedance match 235 by a coaxial cable 224. The impedance match 235 may be a conical impedance match (CIT) in some embodiments. In an embodiment, the impedance match 235 is electrically coupled to the DRA 215. The DRA 215 may be similar to any of the DRAs described in greater detail herein. For example, the DRA 215 may comprise a puck 216 and a pin 217. The pin 217 may be coupled to the impedance match 235 by solder, a connector, or the like. The DRA 215 may be used to couple the microwave power to gasses within the chamber (not shown) in order to initiate and/or sustain a plasma within the chamber.

The impedance match 235 may be used to match an impedance of the DRA 215 to the characteristic impedance of the coaxial cable 224. This is done to reduce (or eliminate) reflected power in the system at a given frequency. For example, at an operating frequency of approximately 2,450 MHz, the impedance of the coaxial cable 224 may be approximately 50 Ohms.

As noted above, high amounts of reflected power can damage the microwave power delivery system 220. When high values of reflected power are detected, the processing may be halted. This can occur in the middle of a processing recipe, and the substrates being processed may not be processed properly. The substrate may need to be scrapped or reworked. Therefore, yields and throughput are negatively impacted. Alternatively, if the tool is not stopped in time, the reflected power can damage the microwave power amplifiers 231 or other components. This increases cost of ownership of the tool, as parts need to be replaced more frequently. Replacing components also results in down time for the tool, which can increase cost of ownership and reduce throughput.

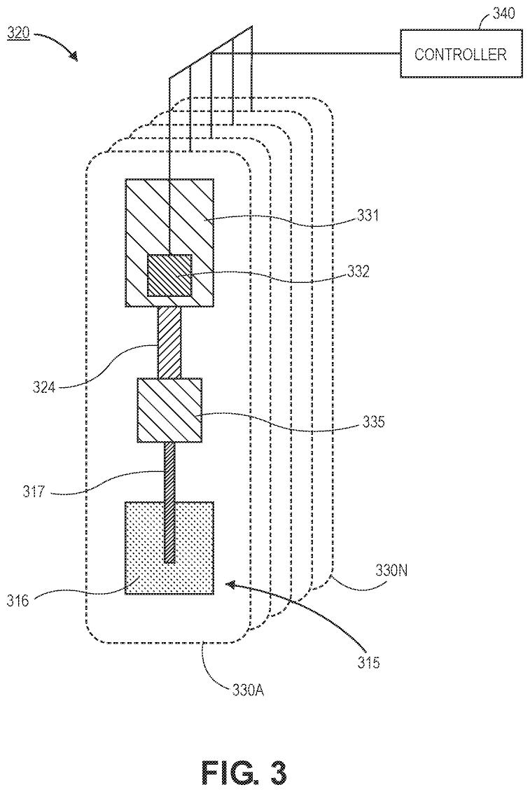

In order to reduce the reflected power, embodiments disclosed herein include microwave power delivery channels that enable dynamic frequency tuning. Particularly, a frequency sweep is implemented in order to find a frequency within the range of the frequency that exhibits the lowest reflected power. After finding the ideal frequency to minimize reflected power, the device continues to monitor reflected power and change the frequency of the microwave power in order to maintain low reflected power levels. A microwave power delivery system 320 capable of providing such dynamic tuning is shown in FIG. 3.

Referring now to FIG. 3, a schematic illustration of a microwave power delivery system 320 is shown, in accordance with an embodiment. In an embodiment, the microwave power delivery system 320 may comprise a plurality of microwave power delivery channels 330A-330N. The number of microwave power delivery channels 330 may match a desired number of antennas (e.g., DRAs 315) that are desired for a microwave plasma tool (not shown).

In an embodiment, each microwave power delivery channel 330 may comprise a microwave power amplifier 331 that is coupled to an impedance match 335 by a coaxial cable 324. In an embodiment, the impedance match 335 may be a fixed match, such as a CIT or the like. In an embodiment, the impedance match 335 is electrically coupled to a DRA 315. The DRA 315 may be similar to any of the DRAs described in greater detail herein. For example, the DRA 315 may comprise a puck 316 and a pin 317. The pin 317 may be coupled to the impedance match 335 by solder, a connector, or the like. The DRA 315 may be used to couple the microwave power to gasses within the chamber (not shown) in order to initiate and/or sustain a plasma within the chamber.

In order to enable dynamic frequency tuning, the power amplifier 331 may comprise a sweep generator 332. The sweep generator 332 may be a component suitable for generating a sweep of a frequency through a range from a first frequency to a second frequency. In some embodiments, the first frequency may be 2,400 MHz and the second frequency may be 2,500 MHz. Though, different ranges may also be used in some embodiments. In some embodiments, the first frequency may refer to a start frequency, and the second frequency may refer to a stop frequency. However, the frequency sweep may also include a range of frequencies that exceeds a range defined by the first frequency and the second frequency. The frequency sweep produced by the sweep generator 332 may be made over a short duration. For example, a duration of the frequency sweep may be up to 100 ms in some embodiments. A scan speed of the frequency sweep may be between 0.5 MHz per millisecond and 5 MHz per millisecond. Though, faster or slower frequency sweeps may also be used in some embodiments.

The sweep generator 332 may be used as part of an initial fast scanning process for the dynamic tuning operation, as will be described in greater detail herein. The sweep generator 332 (or another suitable frequency modulation component) may enable an auto-tuning operation during the dynamic tuning operation. In the auto-tuning portion, the sweep generator may modulate the frequency by between 0.1 MHz per millisecond and 1.0 MHz per millisecond. These smaller changes may be used to see if the reflected power can be reduced during the execution of a process recipe. For example, changing conditions to the load (e.g., plasma) or other chamber conditions may result in changes to the impedance. This may result in increases in reflected power if the auto-tuning operation were not implemented. A more detailed description of the auto-tuning application will be described in greater detail herein.

In an embodiment, the power amplifier 331 may be coupled to a controller 340. More particularly, the sweep generator 332 of the power amplifier 331 may be coupled to the controller 340. The controller 340 may comprise any suitable computer, server, or other computation device. The controller 340 may receive feedback from the microwave power delivery system related to reflected power. For example, a sensor (not shown) for measuring reflected power along each of the microwave power delivery channels 330 may provide a measure of reflected power to the controller 340. The controller 340 uses the feedback in order to control the sweep generator 332 to implement either a frequency sweep and/or an auto-tuning process in order to minimize the reflected power.

In an embodiment, the controller 340 may be coupled to each of the microwave power delivery channels 330A-330N. This allows for simultaneous (also referred to as parallel) control of the frequency tuning across all of the microwave power delivery channels 330 within the microwave power delivery system 320. This provides significant time savings compared to existing solutions where the tuning for each channel is done sequentially. Due to the fast frequency sweeps (e.g., less than 100 milliseconds) and continuous auto-tuning after the frequency sweep, the frequency tuning across the entire microwave power delivery system 320 can be implemented at a beginning of a process recipe (and throughout a process recipe). As noted above, this is a significant benefit compared to existing solutions which need to be tuned before implementing a process recipe. This also allows for more accurate tuning (e.g., reduced reflected power) across multiple process recipes that may include different processing conditions within a single recipe. Accordingly, the operation window of the microwave plasma processing tool is expanded to enable a larger range of applications and/or recipes.

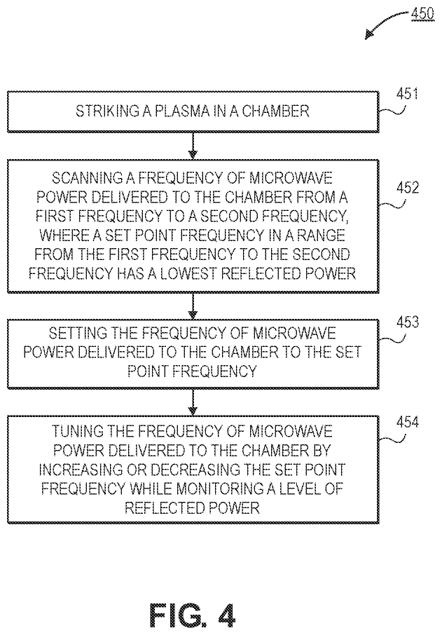

Referring now to FIG. 4, a process 450 for tuning a microwave power delivery system to reduce reflected power during operation is shown, in accordance with an embodiment. In an embodiment, the process 450 may begin with operation 451. In an embodiment, operation 451 may comprise striking a plasma in a chamber. The chamber may be the chamber of a microwave plasma processing tool, such as tool 100 described in greater detail herein. In an embodiment, the plasma strike may take between approximately 1.0 ms and approximately 100 ms. During the plasma strike, the frequency of the microwave power may be substantially constant. The strike frequency may be at a default frequency. For example, the strike frequency may be at 2,450 MHz in some embodiments. The strike frequency may also be set to a frequency determined in a previous iteration of a process recipe. For example, information from previous frequency tuning operations may be used in order to begin a subsequent process.

In an embodiment, the process 450 may continue with operation 452, which comprises scanning a frequency of microwave power delivered to the chamber from a first frequency to a second frequency. In an embodiment, the frequency scanning may be implemented with a sweep generator or the like. In an embodiment, the frequency sweep may be a linear sweep, a stepped sweep, a non-linear sweep, or the like. In some embodiments, the frequency sweep may sometimes be referred to as a “chirp”. The first frequency and the second frequency may be the expected minimum and maximum frequencies suitable for operation of a particular process recipe. For example, the first frequency may be 2,400 MHz and the second frequency may be 2,500 MHz. Though, different first and second frequencies (e.g., with a larger range, a smaller range, or a similar sized range with a different endpoints) may also be used in some embodiments.

In an embodiment, the frequency scan may include a scan speed up to approximately 5.0 MHz per millisecond. For example, a scan speed between 0.5 MHz per millisecond and 5.0 MHz per millisecond may be used in some embodiments. In an embodiment, the frequency scan may have a duration up to approximately 100 ms. More generally, a duration of the frequency scan may be similar to a duration of the plasma strike. The duration of the frequency scan may also be less than 5% of a duration of a pulse in a process recipe, less than 2% of a duration of a pulse in a process recipe, or less than 1% of a duration of a pulse in a process recipe.

In an embodiment, a set point frequency in the range from the first frequency to the second frequency may have a lowest reflected power. That is, during the frequency scan, the reflected power for each of the frequencies is measured (e.g., by a sensor) in order to determine which frequency provides the optimal reflected power performance (i.e., the lowest reflected power).

In an embodiment, the process 450 then continues with operation 453, which may comprise setting the frequency of microwave power delivered to the chamber to the set point frequency. Setting the frequency to the set point frequency starts the process with the ideal reflected power performance.

In an embodiment, the process 450 may continue with operation 454, which comprises tuning the frequency of microwave power delivered to the chamber by changing (e.g., increasing or decreasing) the set point frequency while monitoring a level of reflected power. The operation 454 may sometimes be referred to as an auto tuning operation. In an embodiment, the set point frequency may be changed at regular intervals and/or when the reflected power exceeds a predetermined threshold. The rate at which frequencies may be changed during operation 454 may be up to approximately 2 MHz per millisecond. For example, frequency changes may be implemented at rates between 0.1 MHz per millisecond and 1.0 MHz per millisecond.

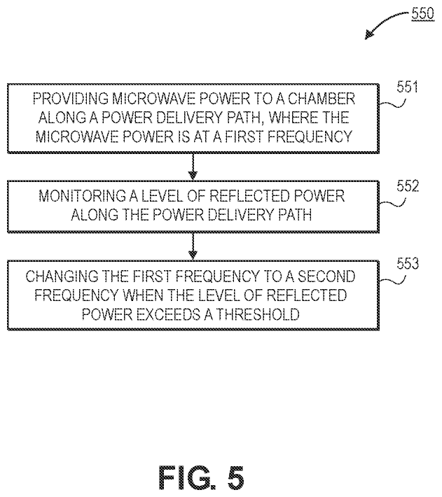

Referring now to FIG. 5, a process flow diagram of a process 550 for implementing the auto-tuning is shown in more detail. In an embodiment, the process 550 may begin with operation 551, which comprises providing microwave power to a chamber along a power delivery path. The power delivery path may be similar to a microwave power delivery channels described in greater detail herein. In an embodiment, the microwave power is at a first frequency. In an embodiment, the first frequency may be the set point frequency determined during a frequency sweep similar to operation 452 described in greater detail above.

In an embodiment, the process 550 may continue with operation 552, which comprises monitoring a level of reflected power along the power delivery path. In an embodiment, a sensor may be integrated into the power delivery path in order to provide a measure of the reflected power.

In an embodiment, the process 550 may continue with operation 553, which comprises changing the first frequency to a second frequency when the level of reflected power exceeds a threshold value. For example, the threshold value may be a percentage of a previously measured level of reflected power. In some embodiments, the threshold level may include an increase in reflected power greater than 1%, greater than 3%, or greater than 5%. That is, when the reflected power increases, the auto-tuning operation may initiate a feedback loop in order to reduce the reflected power.

In an embodiment, the reflected power may change due to any number of reasons. For example, reflected power may increase when conditions (e.g., plasma properties) within a chamber change. This can occur as a process recipe changes a flowrate of gasses into the chamber, power levels change, chamber components wear, etc. Accordingly, the auto-tuning operation allows for flexibility in accommodating plasma processing recipes that have non-uniform process conditions.

In an embodiment, the operations 552 and 553 may be repeated any number of times during a duration of a process recipe. For example, during a single pulse of gas flow into a chamber, operations 552 and 553 may be repeated a plurality of times. The dynamic change of the frequency during a single pulse provides improved performance for the processing tool by maintaining a low reflected power along the power delivery path. As can be appreciated, subsequent iterations of operation 553 may be considered as repeatedly in sequence steps to change plasma strike frequency, to sweep frequency, to auto tune frequency during each process recipe cycle.

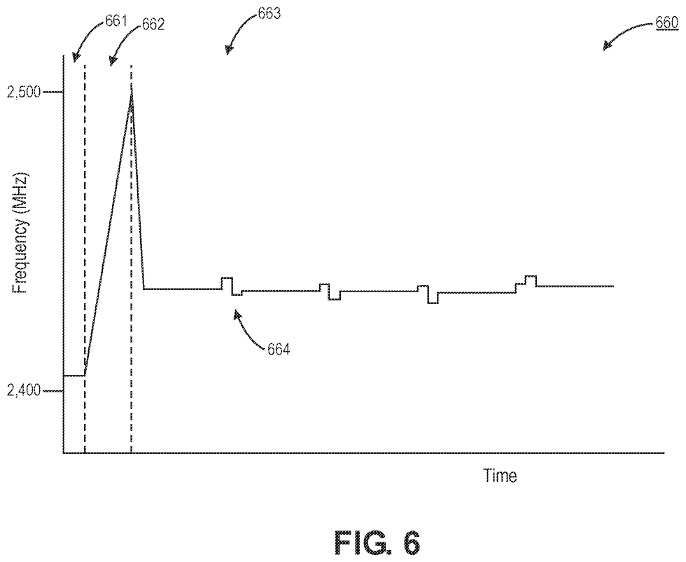

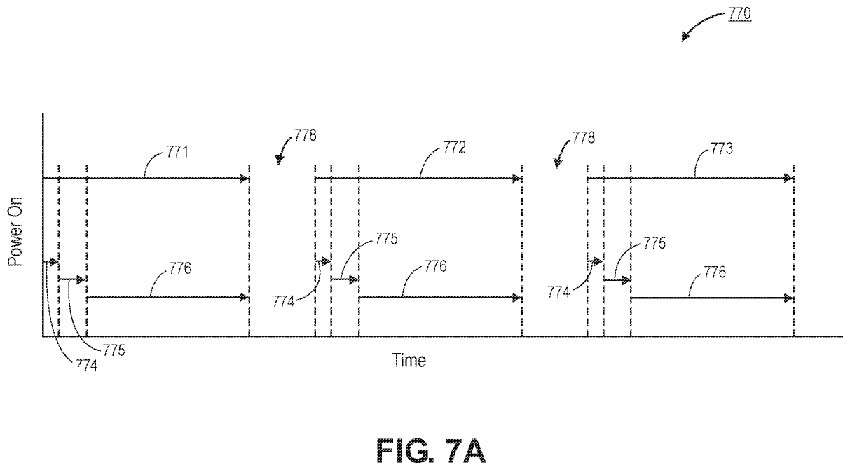

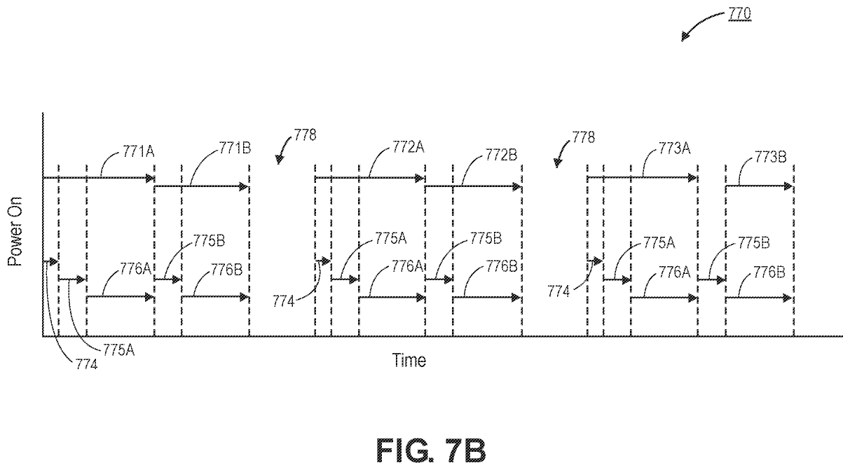

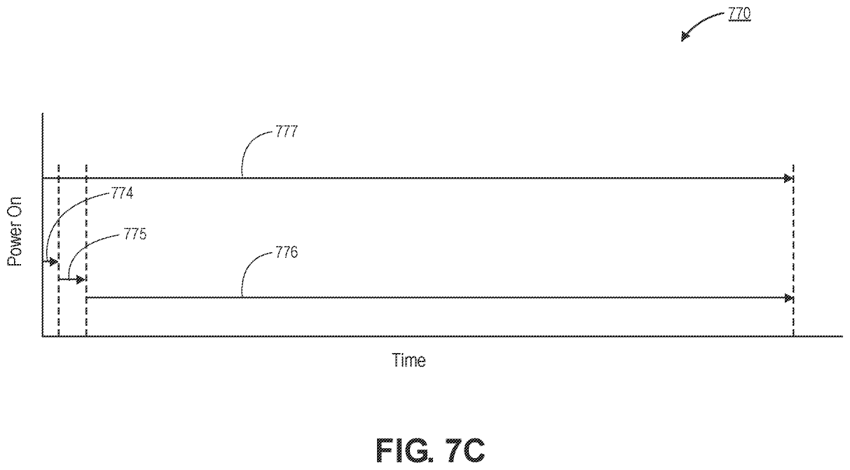

In an embodiment, the processes 450 and 550 may be operated in unison with each other. For example, process 550 may be considered as being a more detailed explanation of operation 454 in process 450. The processes 450 and 550 may be implemented within a single process recipe. The processes 450 and 550 may be executed a single time, or the processes 450 and 550 may be repeated any number of times. Examples of different implementations of processes 450 and 550 are shown with respect to FIG. 6 and FIGS. 7A-7C.

Referring now to FIG. 6, a plot 660 of frequency of the microwave power delivered to a chamber over time is shown, in accordance with an embodiment. In an embodiment, a first duration 661 includes a constant frequency (e.g., around 2,450 MHz) as a plasma is struck in the chamber. The first duration 661 may correspond to operation 451 in process 450. In an embodiment, the first duration 661 may be up to approximately 100 ms.

Thereafter, a second duration 662 shows a frequency sweep similar to operation 452 in process 450. In the plot 660 the frequency sweep is shown as being linear. Though, other sweep patterns (such as those described above) may also be used during the second duration 662. In an embodiment, the sweep during the second duration 662 starts at the constant input frequency from the first duration 661. Though, in other embodiments, the starting frequency of the frequency sweep may be any suitable frequency (e.g., 2,400 MHz).

As noted above, the frequency sweep in the second duration 662 may be used in order to set a set-point frequency during a third duration 663. In an embodiment, the third duration 663 may be considered the auto-tuning region. As shown, tuning operations 664 (e.g., increasing and/or decreasing the frequency) may be implemented in order to maintain low reflected power throughout the process recipe.

Referring now to FIG. 7A, a plot 770 of the frequency tuning process over a process recipe is shown, in accordance with an embodiment. In FIG. 7A, the Y-axis is arbitrary. That is, the Y-position of the various lines is not tied to any value, and the Y-positions are used to more clearly illustrate the break between different operations of the frequency tuning process. In FIG. 7A, the process recipe may include repeated cycles (i.e., pulses) of substantially the same application of a gas and/or process conditions within a plasma chamber. For example, the three pulses 771-773 may be substantially similar to each other in some embodiments. In an embodiment, the pulses 771-773 may be separated by gaps 778. The gaps 778 may be purge cycles, rest cycles, and/or the like.

In an embodiment, each pulse 771-773 may begin with a plasma strike region 774. After the plasma strike region 774, a frequency sweep region 775 is implemented. The frequency sweep region 775 may be similar to operation 452 in process 450. The frequency sweep region 775 may be used to determine a set-point frequency that is then used during the auto-tuning region 776. The auto-tuning region 776 may be similar to operation 454 of process 450 or to process 550. As shown, auto-tuning region 776 may have a longer duration than the plasma strike region 774 and/or the frequency sweep region 775.

Referring now to FIG. 7B, a plot 770 of the frequency tuning process over a process recipe is shown, in accordance with an embodiment. In FIG. 7B, the Y-axis is arbitrary. That is, the Y-position of the various lines is not tied to any value, and the Y-positions are used to more clearly illustrate the break between different operations of the frequency tuning process. In FIG. 7B, the process recipe may include repeated cycles (i.e., pulses) of substantially the same application of a gas and/or process conditions within a plasma chamber. For example, the three pulses 771-773 may be substantially similar to each other in some embodiments. In an embodiment, the pulses 771-773 may be separated by gaps 778. The gaps 778 may be purge cycles, rest cycles, and/or the like.

In an embodiment, each of the pulses 771-773 may comprise a first duration and a second duration (e.g., 771A and 771B, 772A and 772B, and 773A and 773B). The A portion of each pulse may correspond to a first chamber condition, and the B portion of each pulse may correspond to a second chamber condition. For example, the first chamber condition may be a first gas flow rate and/or composition, and the second chamber condition may be a second gas flow rate and/or composition. In one embodiment, a first gas composition may be an inert gas flow, and a second gas composition may be a process gas composition. Though, other embodiments may include two different process gas compositions. Further, while two durations (A and B) are shown for each pulse, it is to be appreciated that any number of durations (for any number of different chamber conditions) may be used in each pulse. Further, while each of the pulses 771-773 are shown as being substantially similar to each other, two or more of the pulses 771-773 may be different from each other.

In an embodiment, the first duration (A) of each pulse 771-773 may begin with a plasma strike region 774. After the plasma strike region 774, a first frequency sweep region 775A is implemented. The first frequency sweep region 775A may be similar to operation 452 in process 450. The first frequency sweep region 775A may be used to determine a first set-point frequency that is then used during the first auto-tuning region 776A. The first auto-tuning region 776A may be similar to operation 454 of process 450 or to process 550.

At the change to the second duration (B) of each pulse 771-773, a second frequency sweep region 775B is implemented. The second frequency sweep region 775B may be similar to the first frequency sweep region 775A. Though, embodiments may also include differences (e.g., different sweep rates, different ranges, etc.) between the first frequency sweep region 775A and the second frequency sweep region 775B. The second frequency sweep region 775B may be used to determine a second set-point frequency that is then used during the second auto-tuning region 776B. The second auto-tuning region 776B may be similar to the first auto-tuning region 776A. Though, embodiments may also include differences (e.g., different thresholds, etc.) between the first frequency auto-tuning region 776A and the second auto-tuning region 776B.

Referring now to FIG. 7C, a plot 770 of the frequency tuning process over a process recipe is shown, in accordance with an embodiment. In FIG. 7C, the Y-axis is arbitrary. That is, the Y-position of the various lines is not tied to any value, and the Y-positions are used to more clearly illustrate the break between different operations of the frequency tuning process. In FIG. 7C, the process recipe may include a single continuous process. For example, the process may be a PECVD process, a plasma treatment process, a plasma cleaning process, or the like. That is, a single process 777 with substantially constant chamber conditions (without any pulses) may be used in some embodiments.

In an embodiment, the process 777 may begin with a plasma strike region 774. After the plasma strike region 774, a frequency sweep region 775 is implemented. The frequency sweep region 775 may be similar to operation 452 in process 450. The frequency sweep region 775 may be used to determine a set-point frequency that is then used during the auto-tuning region 776. The auto-tuning region 776 may be similar to operation 454 of process 450 or to process 550. As shown, auto-tuning region 776 may have a longer duration than the plasma strike region 774 and/or the frequency sweep region 775. The auto-tuning region 776 may continue to the end of the process 777.

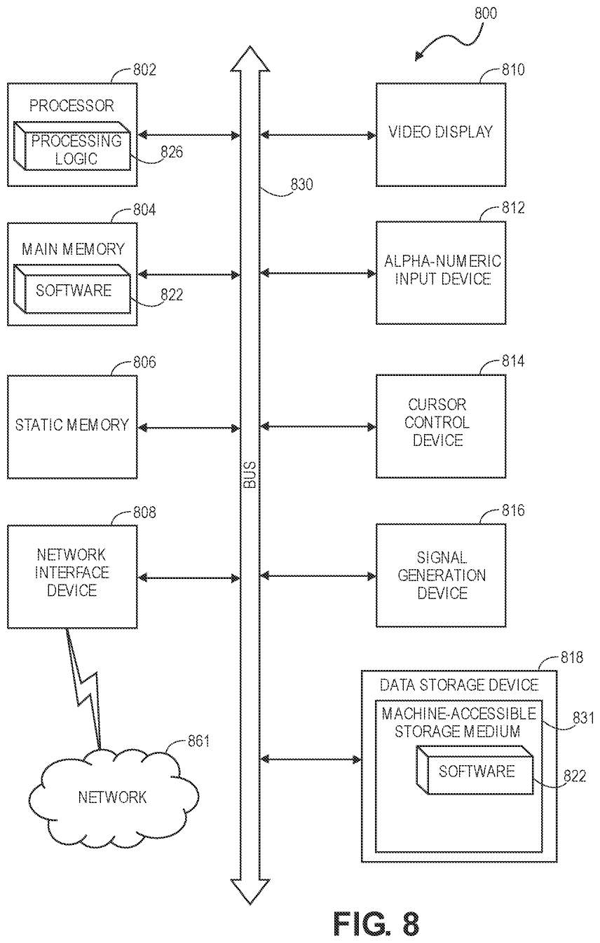

Referring now to FIG. 8, a block diagram of an exemplary computer system 800 of a processing tool is illustrated in accordance with an embodiment. In an embodiment, computer system 800 is coupled to and controls processing in the processing tool. Computer system 800 may be connected (e.g., networked) to other machines in a Local Area Network (LAN), an intranet, an extranet, or the Internet. Computer system 800 may operate in the capacity of a server or a client machine in a client-server network environment, or as a peer machine in a peer-to-peer (or distributed) network environment. Computer system 800 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 800, the term “machine” shall also be taken to include any collection of machines (e.g., computers) that individually or jointly execute a set (or multiple sets) of instructions to perform any one or more of the methodologies described herein.

Computer system 800 may include a computer program product, or software 822, having a non-transitory machine-readable medium having stored thereon instructions, which may be used to program computer system 800 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 800 includes a system processor 802, a main memory 804 (e.g., read-only memory (ROM), flash memory, dynamic random access memory (DRAM) such as synchronous DRAM (SDRAM) or Rambus DRAM (RDRAM), etc.), a static memory 806 (e.g., flash memory, static random access memory (SRAM), etc.), and a secondary memory 818 (e.g., a data storage device), which communicate with each other via a bus 830.

System processor 802 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 802 may also be one or more special-purpose processing devices such as an application specific integrated circuit (ASIC), a field programmable gate array (FPGA), a digital signal system processor (DSP), network system processor, or the like. System processor 802 is configured to execute the processing logic 826 for performing the operations described herein.

The computer system 800 may further include a system network interface device 808 for communicating with other devices or machines. The computer system 800 may also include a video display unit 810 (e.g., a liquid crystal display (LCD), a light emitting diode display (LED), or a cathode ray tube (CRT)), an alphanumeric input device 812 (e.g., a keyboard), a cursor control device 814 (e.g., a mouse), and a signal generation device 816 (e.g., a speaker).

The secondary memory 818 may include a machine-accessible storage medium 831 (or more specifically a computer-readable storage medium) on which is stored one or more sets of instructions (e.g., software 822) embodying any one or more of the methodologies or functions described herein. The software 822 may also reside, completely or at least partially, within the main memory 804 and/or within the system processor 802 during execution thereof by the computer system 800, the main memory 804 and the system processor 802 also constituting machine-readable storage media. The software 822 may further be transmitted or received over a network 861 via the system network interface device 808. In an embodiment, the network interface device 808 may operate using RF coupling, optical coupling, acoustic coupling, or inductive coupling.

While the machine-accessible storage medium 831 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A method for tuning a frequency of microwave power delivered to a chamber, comprising:
striking a plasma in the chamber;
scanning the frequency from a first frequency to a second frequency, wherein a set point frequency in a range from the first frequency to the second frequency has a lowest reflected power;
setting the frequency of the microwave power delivered to the chamber to the set point frequency; and
changing the set point frequency when a measure of reflected power exceeds a threshold.

2. The method of claim 1, wherein the threshold includes an increase in the reflected power that is 5% or more.

3. The method of claim 1, wherein the first frequency is 2,400 MHz and the second frequency is 2,500 MHz.

4. The method of claim 1, wherein scanning the frequency has a duration of up to 100 ms.

5. The method of claim 1, wherein a rate of frequency change during scanning the frequency is up to 5 MHz per millisecond.

6. The method of claim 1, wherein striking the plasma, scanning the frequency, setting the set point frequency, and changing the set point frequency all occur within a single pulse of a processing recipe implemented in the chamber.

7. The method of claim 6, wherein the single pulse further comprises:
scanning the frequency of the microwave power delivered to the chamber from the first frequency to the second frequency a second time, wherein a second set point frequency in the range from the first frequency to the second frequency has the lowest reflected power;
setting the frequency of the microwave power delivered to the chamber to the second set point frequency; and
changing the second set point frequency when the measure of the reflected power exceeds a second threshold.

8. The method of claim 7, wherein the single pulse comprises:
flowing a first gas composition into the chamber for a first duration; and
flowing a second gas composition into the chamber for a second duration after the first duration, wherein scanning the frequency the second time occurs during the second duration.

9. The method of claim 1, further comprising:
simultaneously tuning a plurality of frequencies of the microwave power delivered to the chamber along a plurality of power delivery paths.

10. The method of claim 9, wherein tuning the plurality of frequencies of the microwave power delivered to the chamber along the plurality of power delivery paths is controlled by a controller communicatively coupled to a plurality of power amplifiers along each of the plurality of power delivery paths.

11. An apparatus, comprising:
a microwave power amplifier, wherein the microwave power amplifier comprises a sweep generator;
an impedance match coupled to the microwave power amplifier;
an antenna coupled to the impedance match; and
a controller communicative coupled to the microwave power amplifier and configured to control the sweep generator.

12. The apparatus of claim 11, wherein the impedance match is a fixed impedance match.

13. The apparatus of claim 11, wherein the antenna is a dielectric resonator antenna (DRA).

14. The apparatus of claim 11, wherein the controller is communicatively coupled to a plurality of microwave power amplifiers, wherein each of the plurality of microwave power amplifiers are coupled to an impedance match and an antenna.

15. The apparatus of claim 14, wherein the plurality of microwave power amplifiers comprises ten or more power amplifiers.

16. A method for frequency tuning a multi-channel power amplifier system, comprising:
scanning a plurality of power amplifiers through a frequency range from a first frequency to a second frequency;
setting each of the plurality of power amplifiers to a set point frequency that provides a lowest reflected power; and
auto tuning each of the plurality of power amplifiers during a process recipe, wherein the auto tuning comprises changing the set point frequency for each of the plurality of power amplifiers.

17. The method of claim 16, wherein two or more of the set point frequencies are different from each other.

18. The method of claim 16, wherein the method is implemented for each pulse of the process recipe.

19. The method of claim 16, wherein the plurality of power amplifiers comprises ten or more power amplifiers.

20. The method of claim 16, wherein the process recipe is a plasma enhanced chemical vapor deposition (PECVD) process, a plasma enhanced atomic layer deposition (PEALD) process, a plasma cleaning process, or a plasma treatment process.
